(19) United States
(12) Patent Application Publication
(10) Pub. No.: US 2025/0217537 A1
(43) Pub. Date: Jul. 3, 2025

(54) SYSTEM AND METHOD FOR SIGMA-BASED AND GLIDESLOPE MULTI-PATH PROCESS MODELING

(71) Applicant: THE BANK OF NEW YORK MELLON, New York, NY (US)

(72) Inventors: Yaroslav DENEGA, New York, NY (US); Sridhar M. SEETHARAMAN, New York, NY (US); Kuba JAKOBCZAK, New York, NY (US); Sylwia NOWAK, New York, NY (US)

(21) Appl. No.: 18/651,050

(22) Filed: Apr. 30, 2024

Related U.S. Application Data
(60) Provisional application No. 63/614,996, filed on Dec. 27, 2023.

(51) Int. Cl. G06F 30/17; G06N 7/01

(52) U.S. Cl. CPC G06F 30/17; G06N 7/01

(57) ABSTRACT

A system may use multi-path modeling to determine whether a process will complete on or before a specified time. For example, a system may access a process graph representing a process with multiple tasks, where each task is encoded as a node and each dependency between tasks is encoded as an edge. The system may traverse the process graph to discover pathway parameters. The system may decompose the process graph into multiple paths, each path including one or more tasks. The system may access a last known status for each task and, for each path, determine a probability of finishing on or before the specified time based on the pathway parameters and the last known status. The system may select a dynamic critical path based on the determined probabilities. The probability of completing the process on or before the specified time is determined based on the dynamic critical path.

### CROSS-REFERENCE TO RELATED APPLICATIONS

The subject application claims priority to U.S. Provisional Application No. 63/614,996, filed Dec. 24, 2023, the subject matter of which is incorporated herein by reference in its entirety.

### BACKGROUND

Many processes include a complex network of interconnected and interdependent tasks that need to be executed in a correct order. Furthermore, in many instances, a process must finish on or before a specified time, which can be referred to as a Process Finish Time (PFT). Depending on the context of the process, failure to complete on time can result in various repercussions. Thus, it may be important to identify any problems that may give rise to processing delays.

To this end, some monitoring systems may provide dashboards and other interfaces to show the current state of a running process. However, given the complexity of many processes, these dashboards may be unable to adequately show the progression of the process and any problems. Some computer modeling systems, such as machine learning systems, can learn from empirical data to make predictions on finish times. However, modeling some processes in this way may be problematic, particularly when the models are trained or executed on imperfect data that may skew predictive results. For example, as a process progresses, accurate updates to the process may be unavailable, which may result in improper time predictions. Furthermore, the complexity and scale of the processes may make predictive modeling computationally burdensome. These and other issues may exist with computationally modeling processes for predictive determinations.

### SUMMARY

Various systems and methods may address the foregoing and other problems. For example, to address the problem of complex interdependent tasks in a process, the system may model the process as a process graph. The process graph includes nodes that each represent a task in the process and edges between the nodes that each represent task dependencies. Thus, tasks and their dependencies are modeled as node-edge relationships in the process graph. The system may leverage the node-edge relationships to model the complex interdependencies that may exist in the process. For example, the system may decompose the process graph into a plurality of paths and predict whether each path will complete by a specified time. Each (decomposed) path reflects dependencies, if any, between tasks. Each task in the path may be independent or have one or more dependencies on at least one other task where such dependencies were represented as edges in the process graph.

Once the paths have been decomposed from the process graph, the system may perform path and/or task reduction to reduce the amount of data that must be traversed. This reduction may improve modeling performance by reducing the complexity of the interdependencies and number of tasks or paths to consider. The system may then determine, for each path, a probability that the path will complete on or before the specified time. The system may then identify a dynamic critical path, which is the path having the lowest probability of completing before the specified time. One or more tasks in the dynamic critical path are potentially the most problematic tasks in the process that may cause delays. These tasks may be identified, investigated, and mitigated to ensure that the process is completed on or before the specified time. As the process progresses over time, the system may receive status updates and iterate the predictions based on the status updates to detect problems in real-time or near-real-time to reflect the current status of the process.

To determine the probability that a given path will complete on or before the specified time, the system may use different modeling techniques depending on the particular process being modeled. For example, the system may use Sigma-based modeling and/or Glideslope modeling. Sigma-based modeling may be preferred for paths that have a total duration comparable to the duration of the entire process of which it is a part. Usually, though not necessarily, this occurs when the path consists of one or more relatively long-running tasks. In Sigma-based modeling, the system may learn from prior distributions of task durations. For example, the system may operate on an assumption that all tasks in a path will complete within a mean duration plus the product of a value X and the standard deviation of durations. Based on this assumption, the system will discover a point in time at which all the tasks will be completed.

For certain paths, such as those that include a relatively few number of short-running tasks, Sigma-based modeling may not approximate the data well. For example, Sigma-based modeling may be too late in predicting problems such as tasks that are running too long. In these instances, Sigma-based modeling may reduce the ability to mitigate these problems. For these paths, the system may use Glideslope modeling. Glideslope modeling may select a point in time in which the probability of the path completing before the specified time is adjusted linearly over time. This linear adjustment may enhance sensitivity of detecting when relatively short-running tasks take too long, improving detection capabilities of the system for these tasks.

Through Sigma-based modeling and/or Glideslope modeling, the system may receive real time information about a process as it progresses, and based on this information, determines a probability of the process to be completed on or before a specified time. The system may also provide information about the dynamic critical path to enable mitigation before the process runs too long past the specified time.

### BRIEF DESCRIPTION OF THE DRAWINGS

Features of the present disclosure may be illustrated by way of example and not limited in the following figure(s), in which like numerals indicate like elements, in which:

FIG. 1 illustrates an example of a system for predicting whether a process will complete on or before a specified time such as a Process Finish Time (“PFT”), according to an implementation.

FIG. 2 illustrates an example of a process graph, according to an implementation.

FIG. 3 illustrates a distribution plot of an example distribution of Sigma (o) and mean (u) values plotted against probability density for predicting the probability that a given path in the process will complete by the PFT, according to an implementation.

FIG. 4 illustrates a flowchart of an example method of an optimization function that selects a Sigma Coefficient used in Sigma-based modeling, according to an implementation.

FIG. 4 illustrates a flowchart of an example method for predicting whether a process will complete by a Process Finish Time (“PFT”), according to an implementation.

FIG. 5 illustrates a flowchart of an example method for predicting whether a given path in the process will complete by the PFT using Sigma-based modeling, according to an implementation.

FIG. 6 illustrates a flowchart of an example method for predicting whether a given path in the process will complete by the PFT using Glideslope modeling, according to an implementation.

FIG. 7 illustrates a flowchart of an example method for predicting whether a process will complete on or before a specified time such as the PFT, according to an implementation.

### DETAILED DESCRIPTION

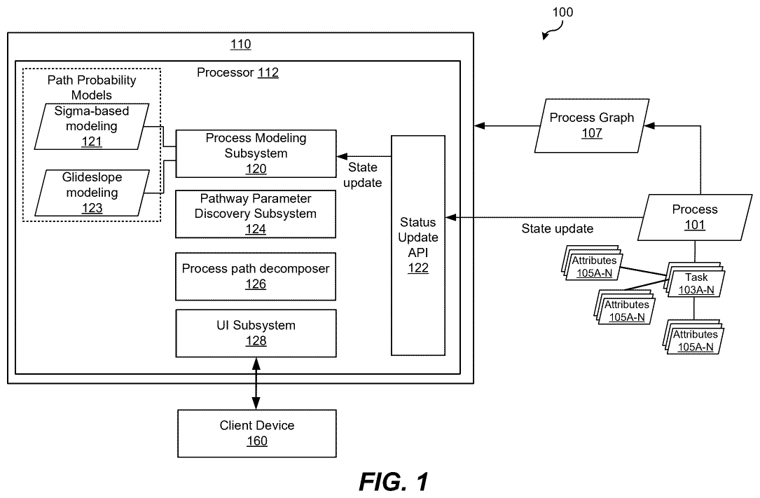

FIG. 1 illustrates an example of a system 100 for predicting whether a process 101 will complete on or before a specified time such as a Process Finish Time (“PFT”), according to an implementation. The specified time may be any time by which a process 101 is to be completed. Examples herein throughout may also refer to this time as a PFT. A process 101 is any process having multiple tasks 103 (illustrated as task 103A-N) that must be completed by a PFT. For a process 101 to be considered complete, at least some, or preferably all, of its tasks 103 must be completed. A PFT is a time and/or date by which the process 101 must be completed. The PFT may be defined by a relative deadline specified by a period of time after the process 101 is started, an absolute deadline regardless of when the process is started, or other type of deadline. Examples of a relative deadline may include, without limitation, a number of minutes, hours, days, weeks, or other duration after the process 101 is started or when another triggering event has occurred. Examples of an absolute deadline may include, without limitation, a specific time or date regardless of when the process 101 is started.

In some implementations, the process 101 may be executed multiple, overlapping, times. For example, a process 101 may be started daily for a week but each daily instance may take more than one day to finish. In this example, each process 101 may be considered an instance of the process 101 and there may be multiple instances running in parallel, which may be independent of one another.

Each process 101 may include a plurality of tasks 103 to be completed. A task 103 is an activity that is completed as part of the process 101. Examples of tasks 103 will vary depending on the particular process 101. For example, in a service level agreement, a task 103 may include implementing a change, creating a deliverable, or other types of tasks 103. In a manufacturing context, a task 103 may include creating, assembling, or installing a part. There may be other types of tasks for other types of processes 101.

Each task 103 may be characterized by task attributes 105 (illustrated as attributes 105A-N). A task attribute 105 is data known about the task, such as task statistics, one or more task dependencies, a time attribute, and/or other data about the task. The task statistics may include empirical data of previously performed tasks such as mean task duration, standard deviation of task duration, and/or other data known about the duration of the task. The task duration may be distributed as a normal distribution and modeled accordingly. However, other types of distribution may occur and be modeled as appropriate.

A task dependency is a coupling of the task 103 to another task 103. For example, a task 103 may have a predecessor dependency and/or a successor dependency. A predecessor dependency is when the task depends on completion of a preceding task before the task is started. A successor dependency is when a succeeding task depends on completion of the task before the succeeding task can start. A given task 103 may have multiple dependencies, which may include more than one predecessor dependency and/or more than one successor dependency. It should be noted that a given task 103 may have zero dependencies.

A time attribute describes a timing aspect of a task associated with an instance of a process 101. Examples of time attributes include a start time, an end time, a duration of the task, a predicted task completion time, and/or other timing aspect of a task in an executing process 101.

Different types of processes 101 may be modeled in the system 100. For example, and without limitation, a process 101 may be associated with a service level agreement and may involve multiple tasks to be completed within a defined deadline, a manufacturing process involving manufacturing tasks that must be completed to complete a product within a defined time, and/or other types of processes having tasks that must be complete by a PFT. The specific PFT will depend on the type of process 101 to be completed.

As shown in FIG. 1, the system 100 may include a computer system 110, one or more client devices 160 (illustrated as client devices 160A,B), and/or other components. The computer system 110 may model and make predictions on whether a process 101 (its process instance) will complete by its PFT.

The computer system 110 may include one or more processors 112 and/or other components. The processor 112 may include one or more of a digital processor, an analog processor, a digital circuit designed to process information, an analog circuit designed to process information, a state machine, and/or other mechanisms for electronically processing information. Although processor 112 is shown in FIG. 1 as a single entity, this is for illustrative purposes only. In some embodiments, processor 112 may comprise a plurality of processing units. These processing units may be physically located within the same device, or processor 112 may represent processing functionality of a plurality of devices operating in coordination.

As shown in FIG. 1, processor 112 is programmed to execute one or more computer program components. The computer program components may include software programs and/or algorithms coded and/or otherwise embedded in processor 112. The one or more computer program components or features may include a process modeling subsystem 120, a status update API 122, a pathway parameter discovery subsystem 124, a process graph decomposer 126, a User Interface (“UI”) subsystem 128, and/or other components or functionality.

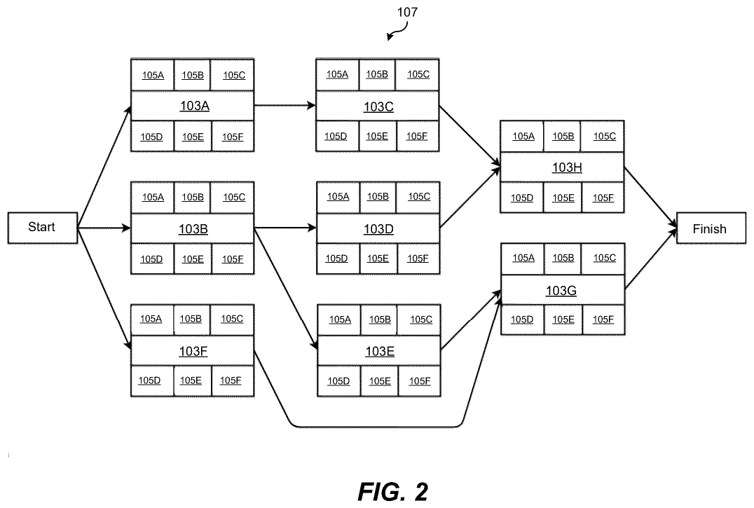

The process modeling subsystem 120 may receive a request to determine whether a process 101 will finish on or before its PFT. For example, the request may be made through the UI subsystem 128, which may provide one or more interfaces for users to request and receive updates regarding the process 101. The request may include a specification of the process 101. One example of how the process 101 may be specified is through a process graph 107. Referring to FIG. 2, which illustrates an example of a process graph 107, a process (such as process 101 illustrated in FIG. 1) encoded by the process graph 107 may include a start 210 and a finish 220. The illustrated process graph 107 may include a plurality of tasks 103 (illustrated as tasks 103A-H). Each task 103 may have a respective plurality of task attributes 105 (illustrated as attributes 105A-F, although a given task 103 may have different numbers of attributes). In some implementations, the process graph 107 may be implemented using an acyclic graph, such as a directed acyclic graph. The task attributes 105 may include empirical data known about the task and/or status updates as a process instance is executed. The empirical data may include task statistics for previously performed tasks such as mean task duration, standard deviation of task duration, and/or other data known about the duration of the task. The updates may include state data from the status update API 122.

A process graph 107 may include a plurality of paths. Each path contains an independent task (a task with no dependencies on other tasks) or multiple tasks with at least one dependency on another task in the same path. For example, four paths are illustrated in FIG. 2 defined by the following tasks:

$$Path 1 \text{:} 103 A \to 103 C \to 103 H$$

$$Path 2 \text{:} 103 B \to 103 D \to 103 H$$

$$Path 3 \text{:} 103 B \to 103 E \to 103 G$$

$$Path 4 \text{:} 103 F \to 103 G$$

As illustrated, a given task may exist in multiple paths. The paths and their respective tasks 103 illustrated in FIG. 2 are for illustrative purposes only. Other paths and other dependencies may exist as well. The duration of a given path, which is the time of time that a path will take, is defined by the duration of each task. For example, the expected duration of path 1 is the sum of the durations of tasks 103A, 103C, and 103H.

When a process 101 starts, the process modeling subsystem 120 may track a process instance for the process 101 in memory such as using a process instance object. The process instance object may itself include task instance objects in which each task instance represents a task in an executing process and each task instance object can store task attributes 105, which may be predefined based on empirical data and/or updated via status updates via the status update API 122.

As a process 101 progresses, the process modeling subsystem 120 may receive updates to the status of the tasks until the process 101 is finished. The updates may include, for each task in the process 101: a task start time, a task finish time, and/or other updates regarding the task. In some examples, the process modeling subsystem 120 may receive the updates via the status update API 122, which itself may receive the updates via updated process graphs 107 that are updated based on the current status of the tasks encoded therein. In some examples, the status update API may receive state data that may be used to update the task attributes so that updated information about each task. In either example, the updates may include a real-time update of each of the task start time and task finish times, some or all of which may have changed since a previous update. Through the updates, the process modeling subsystem 120 may receive regular, real-time or near real-time, status of the progress of the process 101 and its associated tasks.

### Pathway Parameter Discovery Based on Process Graph Traversal

The process modeling subsystem 120 may use the pathway parameter discovery subsystem 124 to access and traverse the process graph 107 to discover a plurality of pathway parameters. A pathway parameter is an attribute of a task (“task attribute”) that describes a time associated with the task. An example of a pathway parameter may include a Critical Pathway Analysis (“CPA”) parameter. A task attribute may include a start time of a task, an end time of a task, a duration of the task, and/or other timing associated with the task. The duration of the task may be based on an estimate. This estimate may be based on an expert opinion, empirically estimated from prior tasks (such as a mean duration of the prior tasks), and/or other sources that may indicate an amount of time that the task should take to complete.

To traverse the process graph 107, the pathway parameter discovery subsystem 124 may perform a forward pass and/or a backward pass. The forward pass assumes a process starts immediately and determines one or more pathway parameters for each task, such as the earliest start time and the earliest finish time. The backward pass assumes a latest finish time of the process is equal to an earliest finish process and determines the following pathway parameters for each task: the latest start time and the latest finish time. Computationally, the time calculations may be performed assuming that the process 101 starts at a computational baseline time, such as given by the function LocalDateTime.MIN.

In some implementations, the pathway parameter discovery subsystem 124 may determine, for each task: a Late Adjusted Start and a Late Adjusted Finish. These times are adjusted based on a specified time, such as the process PFT, For example, the adjustment may be given by: PFT minus the latest time for the process, such as an SLA latest time for the process. These adjusted times may also be respectively referred to as a late PFT adjusted start and a late PFT adjusted finish. By doing so, each task is given a buffer time for completion. For example, a task 103 can start later, but still finish in time for the process 101 to be able to finish on PFT time or earlier.

Decomposing the Process Graph into Constituent Paths for Path Analysis

The process modeling subsystem 120 may use the process graph decomposer 126 to convert the process graph 107 into a plurality of paths (such as Paths 1-4 described with respect to FIG. 2) and generate, for each path, a probability that the path will complete on or before the PFT. The process graph decomposer 126 may then identify the path having the lowest probability of completion on or before the PFT and select that path as the dynamic critical path. The dynamic critical path defines the overall probability that the process 101 will complete on or before the PFT.

To convert the process graph 107, the process graph decomposer 126 may decompose the process graph 107 into paths that cover all the edges and vertices. For example, the process graph decomposer 126 may perform a topological sort on the process graph 107 to obtain a linear ordering of the vertices. This ordering ensures that for any directed edge the proper ordering is achieved. The process graph decomposer 126 may then initialize an empty set of paths and iterate through the topologically sorted order of vertices. For each vertex, the process graph decomposer 126 may create a new path starting with that vertex. The process graph decomposer 126 may then identify the vertex's unvisited neighbors and append each to the path. The process graph decomposer 126 may repeat this path construction process until there are not further unvisited neighboring vertices. The process graph decomposer 126 may add the constructed path to the listing of the plurality of paths decomposed from the process graph 107.

In some implementations, the pathway parameters for each task 103 may be calculated assuming that process 101 starts at the computational baseline time (such as the LocalDateTime.MIN time). As such, the process graph decomposer 126 may adjust the times based on the actual time when the process instance started. Again, after the process 101 is started, the computer system 110 may receive updates regarding the process state, such as described with respect to the status update API 122. Thus, the path completion time prediction of each path may be revised as the process 101 progresses based on any status updates.

### Path and Task Reduction for Improved Probability Determinations

In some implementations, there may be imperfect data regarding the current status of a task instance. For example, the status updates may be unreliable such as by including inaccurate or omitted updates for the task instance. As such, a given task instance that has started or finished may not be reflected in the updated data. To address this problem, the process modeling subsystem 120 may verify task states by determining a status regardless of any incomplete, missing, or otherwise inaccurate status information for a given task instance. For example, if a succeeding task instance has started, the process modeling subsystem 120 may determine that a task instance on which the succeeding task instance depends for completion has already completed. To illustrate, in Path 1 described with respect to FIG. 2 (“Path 1: 103A->103C->103H”), if task 103A has not started according to the task instance attributes for the corresponding task instance, but the task instance for task 103C has started, then the task instance for task 103A will be determined to be completed.

Regardless of the manner in which a task 103 is determined to be complete, the process modeling subsystem 120 may filter out completed tasks from its path. This is because the completed task will no longer be considered when determining a probability that its path will finish before the PFT. Continuing the Path example, if the task instance for task 103A has completed, then the current probability that Path 1 (103A->103C->103H) will complete before the PFT will be based on task 103C and 103H, and not task 103A. If all the tasks in a given path are already completed, the process modeling subsystem 120 may filter out the competed path so that the probability for the finished path is not computed at all. Thus, as the process instance progresses over time, the process modeling subsystem 120 will reduce the number of tasks and paths that are considered, leading to consideration of fewer tasks and paths over time. The task and path reduction may improve performance of the process modeling subsystem 120 by reducing the feature set used for probabilistic determinations for path completion.

### Single Path Completion Probability

The process modeling subsystem 120 may, for each uncompleted path and each of its remaining task instances, determine a path completion probability. A path completion probability is a probability that a given path will complete before the PFT. The process modeling subsystem 120 may use different modeling techniques to determine a path completion probability for each path. For example, the process modeling subsystem 120 may generate a path completion probability for each path in a process using one of different types of path modeling techniques. These path modeling techniques will be referred to as Sigma-based modeling 121 and Glideslope modeling 123. It should be noted that the process modeling subsystem 120 may use Sigma-based modeling 121 on all paths in a process or Glideslope modeling 123 on all paths in the process. Alternatively, the process modeling subsystem 120 may use Sigma-based modeling 121 on at least one path in a process and Glideslope modeling 123 on at least one other path in the process, depending on particular needs and configurations. The decision of whether to use Sigma-based modeling 121 or Glideslope modeling 123 for a given process or a given path in the process may be based on one or more model selection parameters. The model selection parameters may be based on an input parameter (such as from a user requesting probability predictions described herein), an automated selection by the process modeling subsystem 120, and/or other factors. The input parameter may allow a user to select which modeling technique to apply to a given process or a given path in the process. Automated selection may depend on the complexity of the process, and/or other selection criteria. For example, the process modeling subsystem 120 may use Sigma-based modeling 121 for more numerous and/or long-running tasks and Glideslope modeling 123 for fewer and/or shorter-running tasks.

### Sigma-Based Modeling

Sigma-based modeling 121 may be preferred for paths that have a total duration comparable to the duration of the entire process 101 of which it is a part. Usually, though not necessarily, this occurs when the path consists of one or more relatively long-running tasks. In Sigma-based modeling 121, the process modeling subsystem 120 may use a Sigma Coefficient (“SigmaC”) to determine path completion probabilities. In particular, the process modeling subsystem 120 may use the SigmaC to predict the duration of one or more tasks and their respective path. A SigmaC is a number of standard deviations below or above the mean (μ) of a distribution. For example, a SigmaC of −4 refers to four standard deviations below the mean of the distribution while a SigmaC value of +4 refers to four standard deviations below the mean. SigmaC can be numbers other than integers, such as −2.9 or +2.9. SigmaC may be used to quantify deviation of a particular data point from the mean based on number of standard deviations.

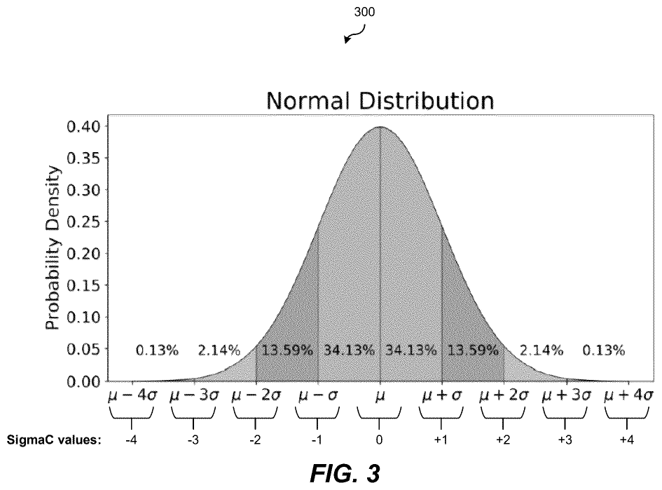

To illustrate, reference will be made to FIG. 3, which illustrates a distribution plot 300 of an example distribution of Sigma (σ) and mean (μ) values plotted against probability density for predicting the probability that a given path in the process will complete by the PFT. In the distribution plot 300, SigmaC={−4, −3, −2, −1, 0, +1, +2, +3, +4} are plotted on the X-axis against a probability density on the Y-axis for an example of path completion probabilities.

For a normal distribution along a two-dimensional distribution plot, the probability that an event will happen before a given value X on an X-axis coordinate, is an area on the graph (such as the Area Under the Curve (“AUC”) for the graph) from minus infinity to X. For example, for SigmaC=+2, it will be 97%, or 0.97 (which is the sum of the AUC up to X=μ+2σ). The probability from minus infinity to SigmaC=+3 is, for practical purposes, 1.0 (100%) (the sum of the AUC up to X=μ+3σ). The probability from minus infinity to SigmaC=−3 is, for practical purposes, 0.0 (0%).

### SigmaC Optimization

In some implementations, the process modeling subsystem 120 may identify an optimal SigmaC based on an optimization function to determine path complete probabilities. An optimal SigmaC is the value of a SigmaC at which a Sigma-adjusted task duration becomes smaller than the available duration for the path to complete. A Sigma-adjusted task duration (TDσ) is an estimate of an expected task duration that is adjusted by a SigmaC. for a particular task. For example, the Sigma-adjusted task duration may be based on the product of μ_{Duration}, σ_{Duration}, and SigmaC, as illustrated in Equation 1:

$$TD σ = {μ}_{Duration} \times {σ}_{Duration} \times SigmaC , \qquad ( 1 )$$

in which:
TDσ=Sigma-adjusted task duration
μ_{Duration}=mean duration of the task based on empirical observations of the duration of the task in the past; and
σ_{Duration}=standard deviation of the empirical observations of the duration of the task in the past.

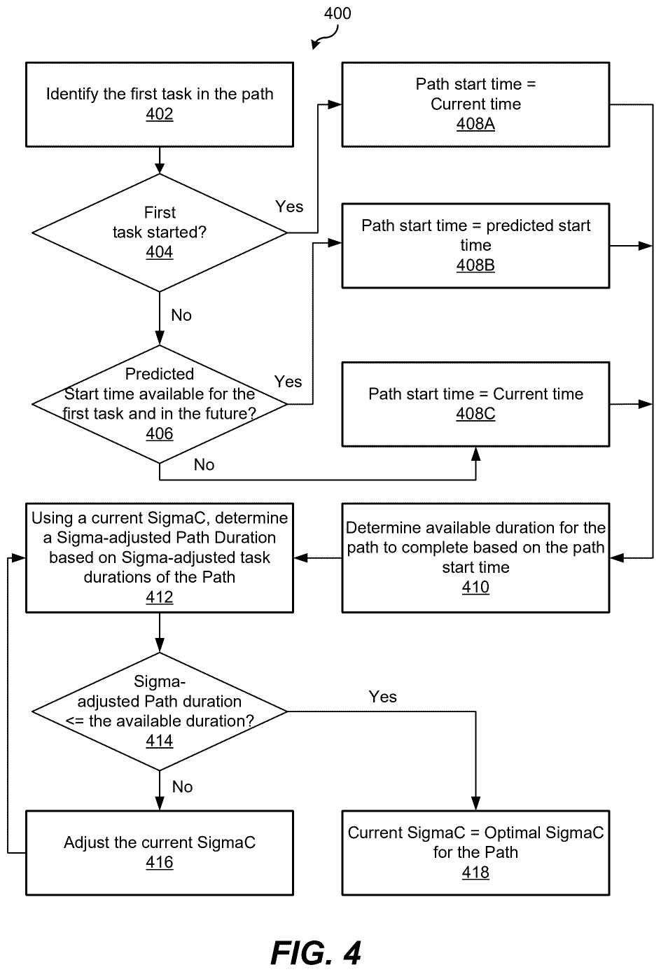

To illustrate, reference will be made to FIG. 4, which illustrates a flowchart of an example method 400 of an optimization function that selects a Sigma Coefficient used in Sigma-based modeling 121. At 402, the method 400 may include identifying a first task in a path. For example, the first task in the path may be identified based on decomposition of a process graph (such as process graph 107 that is converted to individual paths by the pathway parameter discovery subsystem 124). The path start time will be the first task start time, which is the time at which the first task starts. The method 400 may determine the path start time (by determining the first task start time) based on 404 through 408A-C.

At 404, the method 400 may include determining whether the first task started. This determination may be made based on an update to the state of the process instance as described with respect to the status update API 122. If the first task started, at 408A, the method 400 may include setting the path start time to be equal to the current start time of the first task. If the first task has not started, then at 406, the method 400 may include determining whether a predicted start time is available for the first task and whether such predicted start time is in the future. If both are yes, then at 408B, the method 400 may include setting the first task start time to be equal to the predicted start time. If at 406 either is no, then at 408C, the method 400 may include setting the path start time to be equal to the current time.

At 410, the method 400 may include determining an available duration of the path to complete based on the path start time. To determine the available duration of the path, 410 may include subtracting the path start time from the path latest end time. The path latest end time is the late PFT adjusted finish time of the last task in the path.

At 412, the method 400 may include using a current SigmaC to determine a Sigma-adjusted path duration based on Sigma-adjusted task durations of tasks in the path. For an initial iteration, the current SigmaC may be set to a default value, such as +3.0. Other starting values for the current SigmaC may be used as well. For each task in the path, 412 may include determining a Sigma-adjusted task duration based on Equation (1). The Sigma-adjusted path duration may be the sum of these Sigma-adjusted task durations.

The method 400 may include comparing the Sigma-adjusted path duration with the available duration. For example, at 414, the method 400 may include determining whether the Sigma-adjusted path duration is less than or equal to the available duration for the path to complete. If so, at 418, the method 400 may include selecting the current SigmaC as the optimal SigmaC. If not, at 416, the method 400 may include adjusting the current SigmaC by an adjustment increment. For example, if the current SigmaC value is +3.0, the adjustment increment may be −0.1 so that the new current SigmaC value is +2.9. The method 400 may then return to 412 to iterate through the new current SigmaC value.

It should be noted that the value for the adjustment increment may be configurable to be a value other than 0.1. It should be further noted that the adjustment increment may be non-linear, such as being larger around higher numbers of sigma, and smaller in the middle of the graph. Furthermore, although the starting SigmaC value is illustrated as +3.0, other starting values may be used. In some implementations, a starting SigmaC value of −3.0 may be used, in which case the current SigmaC value is iterated until the SigmaC adjusted path duration exceeds the available duration, at which point the last SigmaC value that was did not exceed the available duration is selected as the optimal SigmaC.

### Determining Path Completion Probability Based on SigmaC, Such as the Optimal SigmaC

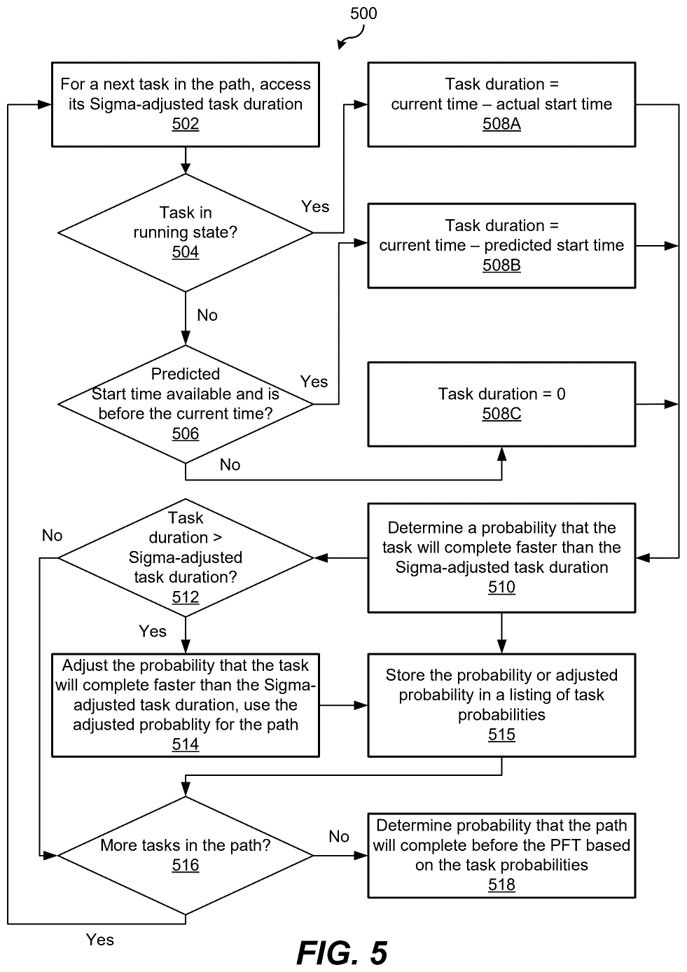

The process modeling subsystem 120 may determine a path completion probability based on a SigmaC value and task durations, such as the optimal SigmaC and Sigma-adjusted task durations determined based on the method 400. To illustrate, attention will now turn to FIG. 5, which illustrates a flowchart of an example method 500 for predicting whether a given path in the process will complete by the PFT using Sigma-based modeling 121.

At 502, the method 500 may include, for each task, accessing its Sigma-adjusted task duration, such as described at 412 of FIG. 4. The method 500 may determine the task duration based on 504 through 508A-C.

At 504, the method 500 may include determining whether the task is in a running state. This information may be obtained based on an update to the state of the process instance as described with respect to the status update API 122. If the task is in a running state, at 508A, the method 500 may include setting the task duration to be the current time minus the actual start time of the task. If the task is not in a running state, at 506, the method 500 may include determining whether a predicted start time is available and is before the current time. If so, at 508B, the method 500 may include setting the task duration to be equal to the current time minus the predicted start time. If the predicted start time of the task is not available or is not before the current time, at 508C, the method 500 may include setting the task duration to be zero.

At 510, the method 500 may include determining, based on the mean task duration, duration standard deviation, and the Sigma-adjusted task duration, the probability that the task will complete faster than the Sigma-adjusted task duration. The probability that the task will complete faster than the Sigma-adjusted task duration may be directly dependent on SigmaC. For example, geometrically, the probability is an area under the graph from minus infinity to Mean plus SigmaC*Sigma, with the total area under the graph from minus infinity to plus infinity is 1.

At 512, the method 500 may include determining whether the task duration is longer than the Sigma-adjusted task duration. If not, then the probability is used without adjustment and stored (such as in a short-term cache or long-term computer memory) in a listing of task probabilities for the path.

If the task duration is longer the Sigma-adjusted task duration (indicating that the task is running longer than expected), at 514, the method 500 may include adjusting the probability that the task will complete faster than the Sigma-adjusted task duration, and then storing the adjusted probability in the listing of probabilities. For example, the adjusted probability may be determined based on Equation (2) if Task duration is less than the sigma-adjusted task duration:

$${P}_{adj} = P \times \frac{PD σ - Task duration}{PD σ} , \qquad ( 2 )$$

in which:
PDσ=Sigma-adjusted path duration as described at 412 of FIG. 4;
Task duration=the task duration as described at 504 through 508A-C;
P=the probability determined at 510; and
P_{adj}=the adjusted probability.

If the Task duration is greater than the sigma-adjusted path duration, then the P_{adj} will be zero.

At 516, the method 500 may include determining whether there are more tasks in the path to be analyzed. If yes, then processing may return to 502 to process the next task.

If not, at 518, the method 500 may include determining a probability that the path will complete before the PFT based on the task probabilities determined at 502-514. For example, the probability that the path will complete before the PFT may be determined based on an average of the task probabilities. One approach may include treating each task as an independent event and therefore multiplying all the task probabilities together. However, this approach may result in precipitous probability drop for the path. For example, if there 15 tasks in the path, and each task has a probability 0.9, the path probability will be 0.915=roughly 0.2. Further reductions of task probabilities will bring the path probability to 0. Thus, path probability should be reduced more gradually. The same Sigma-adjusted duration for each task is used. According to this assumption, if one task in the path runs longer, another can ran faster so that the path can still finish on time. Determining an overall path probability should compensate for this assumption. Accordingly, the method 500 may use an empirical algorithm that gradually reduces path probability over time and does so sufficiently early so that there is enough time available to investigate and rectify potential problems. The resulting empirically-based way to do so was to use the average of the task probabilities. In some implementations, based on these empirical observations or other data, each task probability may be weighted so that a path probability is fine-tuned using weighted averages.

### Glideslope Approach

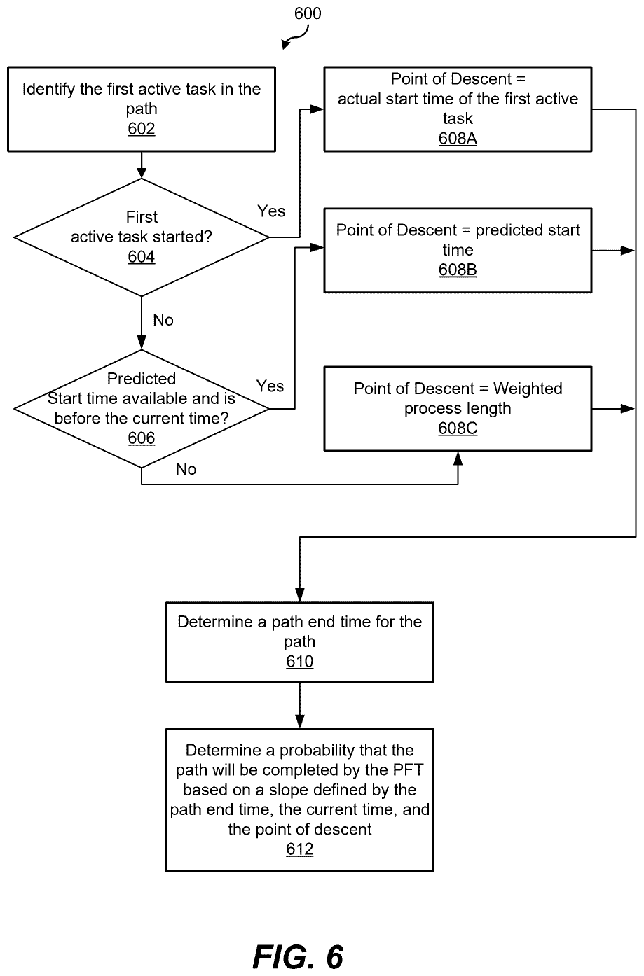

For certain paths, such as those that include a relatively few number of short-running tasks, Sigma-based modeling 121 may not approximate the data well. For example, Sigma-based modeling 121 may be too late in predicting problems such as tasks that are running too long. In these instances, Sigma-based modeling 121 may reduce the ability to mitigate these problems. For these paths, the process modeling subsystem 120 may use Glideslope modeling 123. Glideslope modeling 123 may select a point in time in which the probability of the path completing before the PFT is adjusted linearly over time. To illustrate, reference will be made to FIG. 6. FIG. 6 illustrates a flowchart of an example method 600 for predicting whether a given path in the process will complete by the PFT using Glideslope modeling 123, according to an implementation.

At 602, the method 600 may include identifying the first active task in the path. The term “active task” refers to a task that is in a non-completed state, such as not having been started or currently running. For example, the first task in the path may be identified based on decomposition of a process graph (such as process graph 107 that is converted to individual paths by the pathway parameter discovery subsystem 124). Based on the first task, a point of descent may be identified based on 604 through 608A-C.

At 604, the method 600 may include determining whether the first active task started. This determination may be made based on an update to the state of the process instance as described with respect to the status update API 122. If the first active task started, at 608A, the method 400 may include setting the point of descent time to be equal to the actual start time of the first active task. If the first active task has not started, then at 406, the method 400 may include determining whether a predicted start time is available for the first active task and whether such predicted start time is in the future. If both are yes, then at 608B, the method 400 may include setting the point of descent time to be equal to the predicted start time. If at 606 either is no, then at 608C, the method 600 may include setting the point of descent time to be equal to a weighted value of the expected duration of the process to which the path belongs. The weighted value may be a proportion of the expected duration. For example, the weighted value may be 0.75× the expected duration (three-quarters of the expected duration).

At 610, the method 600 may include determining a path end time for the path. The path end time may be defined by the PFT of the process, which may be the same as the Late PFT Adjusted Finish of the last Task of the Path.

At 612, the method 600 may include determining a probability that the path will be completed by the PFT based on a slope defined by the path end time, the current time, and the point of descent time. For example, the probability, P, may be determined based on Equation (3):

$$P = \frac{path end time - current time}{path end time - point of descent time} . \qquad ( 3 )$$

The UI subsystem 128 may generate updates on the process 101, including data accessed or generated by the computer system 110 in connection with the process 101. The UI subsystem 128 may provide the updates via messaging (such as electronic mail, Short Message Service text message, intra-application notifications), one or more interfaces for transmission to users (such as through client devices 160), and/or other ways in which the updates may be transmitted.

In some implementations, via the UI subsystem 128, users may provide one or more update parameters that configure how and what data is provided by the computer system 110 as the process 101 progresses. The update parameters may include, without limitation, a request type parameter, an update frequency parameter, a model selection input, and/or other options for receiving updates. The request type parameter may specify whether updates are to be pulled from the computer system 110 and/or pushed by the computer system to the client device 160. A pull update is one in which a client device 160 specifically transmits a request for the update. A push update is one in which the computer system 110 transmits the update to the client device 160 without an express request from the client device for that particular update. Push updates may be triggered by an event that occurred in the process 101 (such as the completion of one or more tasks or paths), a passage of a time interval, which may be defined by the update frequency parameter, and/or other triggering event.

Whether pushed or pulled, the update may include state data regarding one or more tasks of each path. The state data may include one or more of the task attributes for each task, one or more probabilities that have been determined by the computer system 110, and/or other data determined or accessed by the computer system 110. In this manner, users may be timely notified of any problems in the process 101.

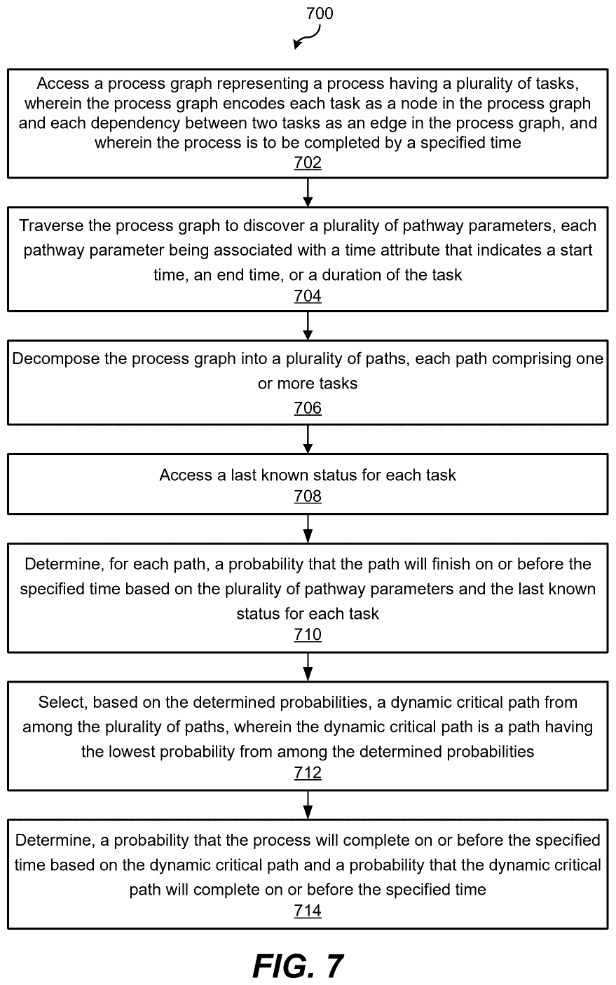

FIG. 7 illustrates a flowchart of an example method 700 for predicting whether a process 101 will complete on or before a specified time such as the PFT, according to an implementation.

At 702, the method 700 may include accessing a process graph (such as process graph 107). The process graph may represent the process 101, which may include a plurality of tasks 103. The process graph encodes each task 103 as a node in the process graph 107 and each dependency between two tasks as an edge in the process graph 107. The process 101 is to be completed by the specified time, such as the PFT.

At 704, the method 700 may include traversing the process graph to discover a plurality of pathway parameters. Each pathway parameter may be associated with a time attribute that indicates a start time, an end time, or a duration of the task. An example of discovering pathway parameters is described with respect to the pathway parameter discovery subsystem 124. An example of a pathway parameter may include a CPA parameter for critical path analysis.

At 706, the method 700 may include decomposing the process graph into a plurality of paths, each path comprising one or more tasks. Examples of paths (Paths 1-4) are described with reference to FIG. 2, as decomposed by the process graph decomposer 126.

At 708, the method 700 may include accessing a last known status for each task. For example, the last known status for each task may be based on updates as described with respect to the status update API 122.

At 710, the method 700 may include determining, for each path, a probability that the path will finish on or before the specified time based on the plurality of pathway parameters and the last known status for each task. These path probabilities may be determined based on Sigma-based modeling 121 and/or Glideslope modeling 123.

At 712, the method 700 may include selecting, based on the determined probabilities, a dynamic critical path from among the plurality of paths, wherein the dynamic critical path is a path having the lowest probability from among the determined probabilities.

At 714, the method 700 may include determining a probability that the process will complete on or before the specified time based on the dynamic critical path and a probability that the dynamic critical path will complete on or before the specified time.

Processor 112 may be configured to execute or implement 120, 121, 122, 123, 124, 126, 128 by software; hardware; firmware; some combination of software, hardware, and/or firmware; and/or other mechanisms for configuring processing capabilities on processor 112. It should be appreciated that although 120, 121, 122, 123, 124, 126, 128 are illustrated in FIG. 1 as being co-located in the computer system 110, one or more of the components or features 120, 121, 122, 123, 124, 126, 128 may be located remotely from the other components or features. The description of the functionality provided by the different components or features 120, 121, 122, 123, 124, 126, 128 described below is for illustrative purposes, and is not intended to be limiting, as any of the components or features 120, 121, 122, 123, 124, 126, 128 may provide more or less functionality than is described, which is not to imply that other descriptions are limiting. For example, one or more of the components or features 120, 121, 122, 123, 124, 126, 128 may be eliminated, and some or all of its functionality may be provided by others of the components or features 120, 121, 122, 123, 124, 126, 128, again which is not to imply that other descriptions are limiting. As another example, processor 112 may include one or more additional components that may perform some or all of the functionality attributed below to one of the components or features 120, 121, 122, 123, 124, 126, 128.

Each of the computer system 110 and client devices 160 may also include memory in the form of electronic storage. The electronic storage may include non-transitory storage media that electronically stores information. The electronic storage media of the electronic storages may include one or both of (i) system storage that is provided integrally (e.g., substantially non-removable) with servers or client devices or (ii) removable storage that is removably connectable to the servers or client devices via, for example, a port (e.g., a USB port, a firewire port, etc.) or a drive (e.g., a disk drive, etc.). The electronic storages may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. The electronic storages may include one or more virtual storage resources (e.g., cloud storage, a virtual private network, and/or other virtual storage resources). The electronic storage may store software algorithms, information determined by the processors, information obtained from servers, information obtained from client devices, or other information that enables the functionalities described herein.

The computer system 110 and the one or more client devices 160 may be connected to one another via a communication network (not illustrated), such as the Internet or the Internet in combination with various other networks, like local area networks, cellular networks, or personal area networks, internal organizational networks, and/or other networks. It should be noted that the computer system 110 may transmit data, via the communication network, conveying the predictions one or more of the client devices 160. The data conveying the predictions may be a user interface generated for display at the one or more client devices 160, one or more messages transmitted to the one or more client devices 160, and/or other types of data for transmission. Although not shown, the one or more client devices 160 may each include one or more processors, such as processor 112.

The systems and processes are not limited to the specific implementations described herein. In addition, components of each system and each process can be practiced independent and separate from other components and processes described herein. Each component and process also can be used in combination with other assembly packages and processes. The flow charts and descriptions thereof herein should not be understood to prescribe a fixed order of performing the method blocks described therein. Rather the method blocks may be performed in any order that is practicable including simultaneous performance of at least some method blocks. Furthermore, each of the methods may be performed by one or more of the system features illustrated in FIG. 1.

This written description uses examples to disclose the implementations, including the best mode, and to enable any person skilled in the art to practice the implementations, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A computer system to generate a probability that a path in a process will complete before a specified time, the path having a plurality of tasks, the system comprising: a processor programmed to:
access a sigma coefficient associated with the path, the sigma coefficient being a number of standard deviations below or above a mean of a distribution of probability densities to predict that the path will complete before the specified time;
for each task in the path: determine a task duration for the task based on whether or not the task is in a running state; generate a Sigma-adjusted task duration based on a mean task duration of previous durations of the task, a standard deviation of the previous durations of the task, and the sigma coefficient;
generate a probability that the task will complete faster than the Sigma-adjusted task duration;
determine whether or not the task duration is greater than the Sigma-adjusted task duration; determine whether or not to adjust the probability that the task will complete faster than the Sigma-adjusted task duration based on whether or not the task duration is greater than the Sigma-adjusted task duration;
store the probability that the task will complete faster than the Sigma-adjusted task duration or the adjusted probability in a listing of task probabilities; and
determine a probability that the path will complete before the specified time based on the listing of task probabilities.

2. The system of claim 1, wherein the sigma coefficient is initially predefined, and wherein the processor is further programmed to:
adjust the sigma coefficient based on an optimization function that selects an appropriate sigma coefficient to use specifically for the path.

3. The system of claim 2, wherein to adjust the sigma coefficient, the processor is further programmed to: (i) identify a path start time for the path based on a start time of a first task in the path; (ii) determine an available duration for the path to complete based on the path start time and the specified time; (iii) generate a Sigma-adjusted path duration based on the sigma coefficient and the Sigma-adjusted task durations that were each determined for each task; (iv) compare the Sigma-adjusted path duration with the available duration; and (v) adjust the sigma coefficient by an adjustment increment based on the comparison.

4. The system of claim 3, wherein to compare the Sigma-adjusted path duration with the available duration, the processor is further programmed to:
determine that the Sigma-adjusted path duration is less than or equal to the available duration, wherein the sigma coefficient is adjusted responsive to the determination that the Sigma-adjusted path duration is less than or equal to the available duration.

5. The system of claim 3, wherein the processor is further programmed to:
iterate (iii) through (v) until the Sigma-adjusted path duration is less than or equal to the available duration and select the adjusted sigma coefficient when the Sigma-adjusted path duration is less than or equal to the available duration.

6. A method for multi-path modeling, comprising:
accessing, by a processor, a process graph representing a process having a plurality of tasks, wherein the process graph encodes each task as a node in the process graph and each dependency between two tasks as an edge in the process graph, and wherein the process is to be completed by a specified time;
traversing, by the processor, the process graph to discover a plurality of pathway parameters, each pathway parameter being associated with a time attribute that indicates a start time, an end time, or a duration of the task;
decomposing, by the processor, the process graph into a plurality of paths, each path comprising one or more tasks;
accessing, by the processor, a last known status for each task; determining, for each path, by the processor, a probability that the path will finish on or before the specified time based on the plurality of pathway parameters and the last known status for each task;
selecting, by the processor, based on the determined probabilities, a dynamic critical path from among the plurality of paths, wherein the dynamic critical path is a path having the lowest probability from among the determined probabilities; and
determining, by the processor, a probability that the process will complete on or before the specified time based on the dynamic critical path and a probability that the dynamic critical path will complete on or before the specified time.

7. The method of claim 6, further comprising:
for each path and each task in the path:
determining a plurality of forward pathway parameters based on a forward pass of the process graph; and
determining a plurality of backward pathway parameters based on a backward pass of the process graph.

8. The method of claim 6, further comprising:
determining, for each task, based on the specified time, a late-adjusted start and a late-adjusted finish that each provide a buffer time for the task to complete.

9. The method of claim 6, wherein determining, by the processor, for each path, a probability that the path will finish on or before the specified time comprises:
determining, for each path, the probability using Sigma-based modeling.

10. The method of claim 6, wherein determining, by the processor, for each path, a probability that the path will finish on or before the specified time comprises:
for each path:
identifying a point of descent based on a start time of a first active task in the path;
determining a path end time for the path; and
determining the probability that the path will be completed by the specified time based on a slope defined by the path end time, a current time, and the point of descent.

11. The method of claim 6, further comprising:
initializing a process instance data structure that stores data relating to the process and a plurality of task instance structures that each represents and stores data relating to a respective task; and
storing the plurality of pathway parameters as part of the task instance.

12. The method of claim 6, further comprising:
receiving one or more state updates as the process progresses;
updating, based on the one or more state updates, for each path, the probability that the path will finish on or before the specified time based on the plurality of pathway parameters and the last known status for each task;
re-selecting, based on the one or more state updates and the updated probabilities, the dynamic critical path from among the plurality of paths; and
updating, based on the one or more state updates, the probability that the process will complete on or before the specified time based on the dynamic critical path and a probability that the dynamic critical path will complete on or before the specified time.

13. The method of claim 6, further comprising:
determining that a particular task in a particular path, from among the plurality of paths, is complete or that a successor task that depends on the particular task has started; and filtering out the particular task when determining a probability that the particular task will complete before the specified time.

14. The method of claim 6, further comprising:
determining that a particular path, from among the plurality of paths, is complete; and
filtering out the particular path when determining the probability that the process will complete before the specified time.

15. The method of claim 6, wherein the process is associated with a service level agreement and the specified is a process finish time relating to the service level agreement.

16. A non-tangible computer readable medium storing instructions to perform multi-path modeling, the instructions, when executed by a processor, programs the processor to:
access a process graph representing a process having a plurality of tasks, wherein the process graph encodes each task as a node in the process graph and each dependency between two tasks as an edge in the process graph, and wherein the process is to be completed by a specified time;
traverse the process graph to discover a plurality of pathway parameters, each pathway parameter being associated with a time attribute that indicates a start time, an end time, or a duration of the task;
decompose the process graph into a plurality of paths, each path comprising one or more tasks;
access a last known status for each task;
determine, for each path, a probability that the path will finish on or before the specified time based on the plurality of pathway parameters and the last known status for each task;
select, based on the determined probabilities, a dynamic critical path from among the plurality of paths, wherein the dynamic critical path is a path having the lowest probability from among the determined probabilities; and
determine, a probability that the process will complete on or before the specified time based on the dynamic critical path and a probability that the dynamic critical path will complete on or before the specified time.

17. The non-tangible computer readable medium of claim 16, wherein the instructions, when executed by the processor, further programs the processor to:
determine, for each path, the probability using Sigma-based modeling.

18. The non-tangible computer readable medium of claim 16, wherein the instructions, when executed by the processor, further programs the processor to:
for each path:
identify a point of descent based on a start time of a first active task in the path;
determine a path end time for the path; and
determine the probability that the path will be completed by the specified time based on a slope defined by the path end time, a current time, and the point of descent.

19. The non-tangible computer readable medium of claim 16, wherein the instructions, when executed by the processor, further programs the processor to:
determine that a particular task in a particular path, from among the plurality of paths, is complete or that a successor task that depends on the particular task has started; and
filter out the particular task when determining a probability that the particular task will complete before the specified time.

20. The non-tangible computer readable medium of claim 16, wherein the instructions, when executed by the processor, further programs the processor to:
determine that a particular path, from among the plurality of paths, is complete; and
filter out the particular path when determining the probability that the process will complete before the specified time.
